(19) United States
(12) Patent Application Publication
(10) Pub. No.: US 2010/0315134 A1
(43) Pub. Date: Dec. 16, 2010

(54) SYSTEMS AND METHODS FOR MULTI-LANE COMMUNICATION BUSSES

(75) Inventor: Sharad Murari, Gilbert, AZ (US)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/867,500

(22) PCT Filed: Mar. 2, 2009
(86) PCT No.: PCT/IB09/50833

§ 371 Date: Aug. 13, 2010

(30) Foreign Application Priority Data
Feb. 28, 2008 (US) 61032328
Mar. 2, 2009 (IB) PCT/IB2009/050833

(51) Int. Cl. H03L 7/00

(52) U.S. Cl. 327/145

(57) ABSTRACT

Multi-lane PCI express busses devices, methods and systems are implemented in various fashions. According to one such implementation, a method is used for synchronizing data transfers between IC dies of a plurality of integrated-circuits (IC) dies. In a first IC die, a synchronizing signal is received and latched in a first clock domain and in the first IC die to produce a first latched output signal. The latched output signal is provided for use by each of the plurality of IC dies. In each of the plurality of IC dies, the first latched output signal is latched in the first clock domain to produce a second latched output signal. The second latched output signal is latched in a second clock domain to produce a third latched output signal. The third latched output signal is used to synchronize a respective communication lane.

The present invention relates generally to methods and system for use with a communication bus, and in particular to systems and methods for multi-lane PCI express busses.

Many different types of electronic communications are carried out for a variety of purposes and with a variety of different types of devices and systems. One type of electronic communications system involves those communications associated with point-to-point bus communications between two or more different components. For instance, computers typically include a central processing unit (CPU) that communicates with peripheral devices via a bus. Instructions and other information are passed between the CPU and the peripheral devices on a communications bus or other link.

One type of communications approach involves the use of a PCI (Peripheral Component Interconnect) system. PCI is an interconnection system between a microprocessor and attached devices in which expansion slots are spaced closely for high speed operation. Using PCI, a computer can support new PCI cards while continuing to support Industry Standard Architecture (ISA) expansion cards, which is an older standard. PCI is designed to be independent of microprocessor design and to be synchronized with the clock speed of the microprocessor. PCI uses active paths (on a multi-drop bus) to transmit both address and data signals, sending the address on one clock cycle and data on the next. The PCI bus can be populated with adapters requiring fast accesses to each other and/or system memory and that can be accessed by a host processor at speeds approaching that of the processor's full native bus speed. Read and write transfers over the PCI bus are implemented with burst transfers that can be sent starting with an address on the first cycle and a sequence of data transmissions on a certain number of successive cycles. PCI-type architecture is widely implemented, and is now installed on most desktop computers.

PCI Express architecture exhibits similarities to PCI architecture with certain changes. PCI Express architecture employs a switch that replaces the multi-drop bus of the PCI architecture with a switch that provides fan-out for an input-output (I/O) bus. The fan-out capability of the switch facilitates a series of connections for add-in, high-performance I/O. The switch is a logical element that may be implemented within a component that also contains a host bridge. A PCI switch can be conceptualized as a collection of PCI-to-PCI bridges in which one bridge is the upstream bridge that is connected to a private local bus via its downstream side to the upstream sides of a group of additional PCI-to-PCI bridges.

In PCI Express applications an interconnection bus is used to transmit data between devices. Unlike a PCI bus, the PCI-Express bus uses a serial bus to transmit data between devices. The bandwidth of a PCI Express link between two devices can be scaled by adding multiple lanes between the two devices, where each lane is a serial bus. The current specification supports ×1, ×4, ×8, and ×16 lane widths. The data is striped across the links accordingly. The PCI-Express devices negotiate lane widths and frequency of operation between one another and then the striped data bytes are transmitted with 8b/10b encoding.

To support the scaling of PCI Express link, the PCI Express specification defines a number of signal-timing criteria that must be met. When each of the lanes is contained within a single integrated circuit (IC) chip, problems meeting the signal-timing criteria can generally be minimized by judicious layout of the traces within the IC chip. The complexity, size and cost of the IC chip generally increase as the number of lanes increases.

Various aspects of the present invention are directed to systems, methods, arrangements and circuits for synchronizing integrated-circuit (IC) dies.

Consistent with one embodiment, a method is used for synchronizing data transfers between a plurality of integrated-circuits (IC) dies, each IC including a physical layer (PHY) and a communication lane. In a first IC die of the plurality of integrated-circuits (IC) dies, a synchronizing signal is received and latched in a first clock domain to produce a first latched output signal. The latched output signal is provided for use by each of the plurality of integrated-circuits (IC) dies. In each of the plurality of integrated-circuits (IC) dies, the first latched output signal is latched in the first clock domain to produce a second latched output signal. The second latched output signal is latched in a second clock domain to produce a third latched output signal. The third latched output signal is used to synchronize a respective communication lane. In one instance, the second clock domain is phase-locked with the first clock domain and a frequency of second clock domain is faster than a frequency of the first clock domain.

Consistent with another embodiment of the present invention, a device synchronizes data transfers between a plurality of integrated-circuits (IC) dies. Each IC die includes a physical layer (PHY) and a communication lane. A first IC die of the plurality of integrated-circuits (IC) dies receives a synchronizing signal. In the first IC die, a master circuit latches the synchronizing signal in a first clock domain to produce a first latched output signal and to provide the first latched output signal for use by each of the plurality of integrated-circuits (IC) dies. In each of the plurality of integrated-circuits (IC) dies, a first circuit latches the first latched output signal in the first clock domain to produce a second latched output signal. A second circuit latches the second latched output signal in a second clock domain to produce a third latched output signal. A third circuit uses the third latched output signal to synchronize a respective communication lane. In one instance, the second clock domain is phase-locked with the first clock domain and a frequency of second clock domain is faster than a frequency of the first clock domain.

Consistent with another embodiment of the present invention, a system synchronizes data transfers between a plurality of integrated-circuits (IC) dies, each IC die including a physical layer (PHY) and a communication lane. The system has a control circuit for generating a synchronizing signal. The synchronizing signal is received in a master IC die of the plurality of integrated-circuits (IC) dies. A master circuit latches the synchronizing signal in a first clock domain and in the first IC die to produce a first latched output signal and to provide a first latched output signal to each of the plurality of integrated-circuits (IC) dies. In each of the plurality of integrated-circuits (IC) dies, a first circuit latches the first latched output signal in the first clock domain to produce a second latched output signal. A second circuit latches the second latched output signal in a second clock domain to produce a third latched output signal. A third circuit uses the third latched output signal to synchronize a respective communication lane. In one instance, the second clock domain is phase-locked with the first clock domain and a frequency of second clock domain is faster than a frequency of the first clock domain.

The above summary is not intended to describe each embodiment or every implementation of the present disclosure. The figures and detailed description that follow more particularly exemplify various embodiments.

The invention may be more completely understood in consideration of the following detailed description of various embodiments of the invention in connection with the accompanying drawings, in which:

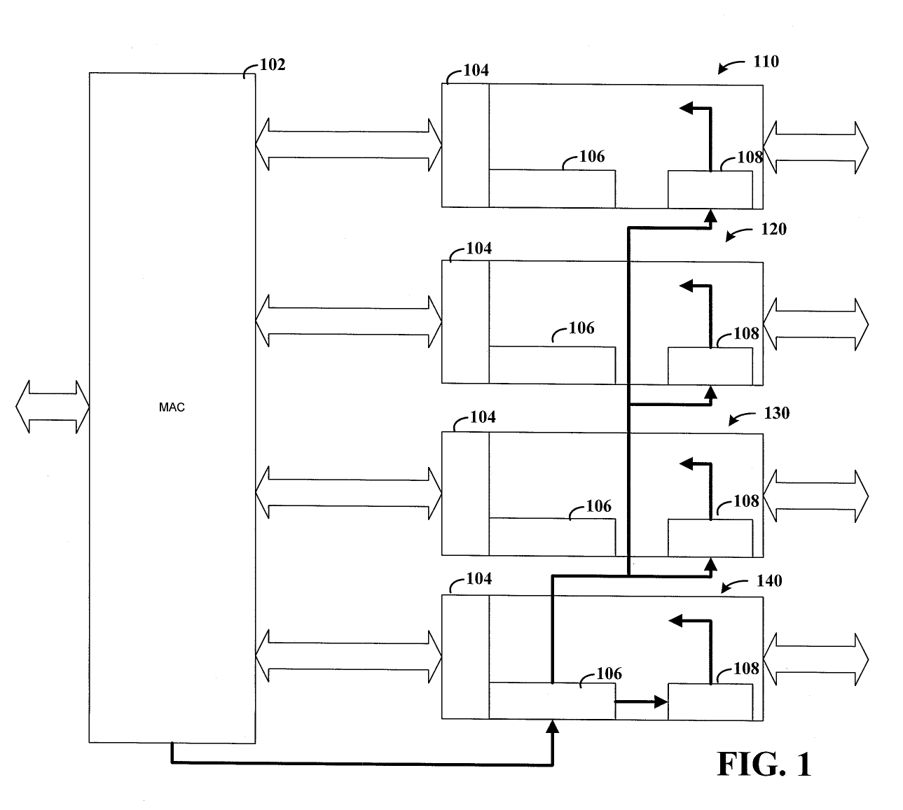

FIG. 1 shows a block diagram representing a communication system having a cascaded PHY, consistent with an example embodiment of the present invention;

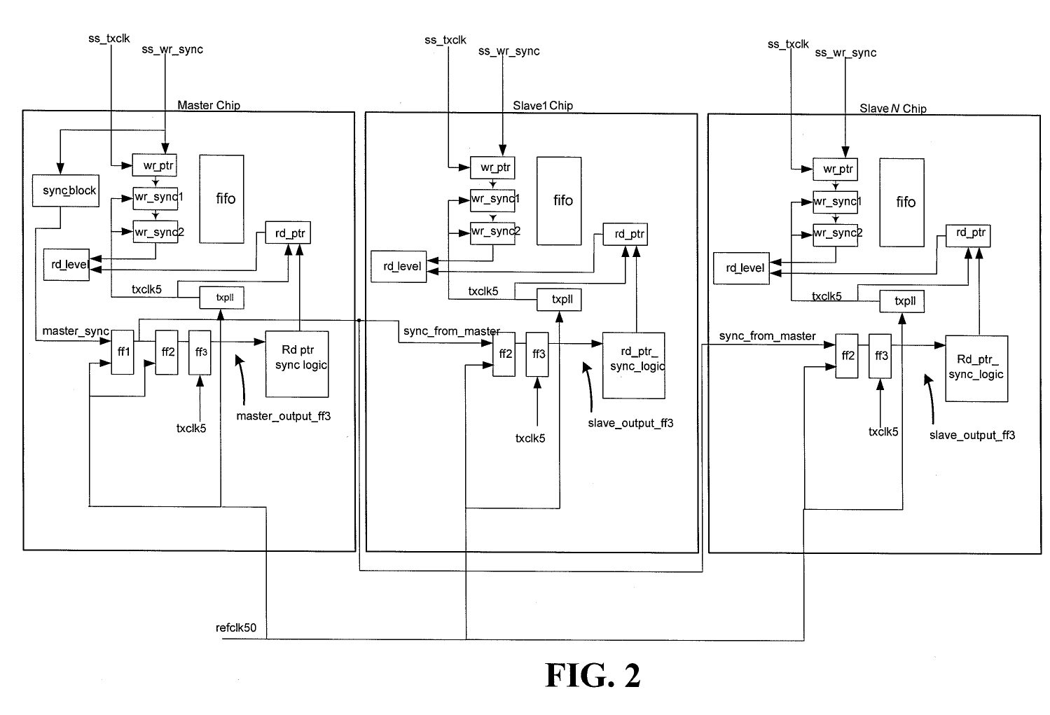

FIG. 2 shows a block diagram representing components of a system for implementing a cascaded PHY, according to an example embodiment of the present invention;

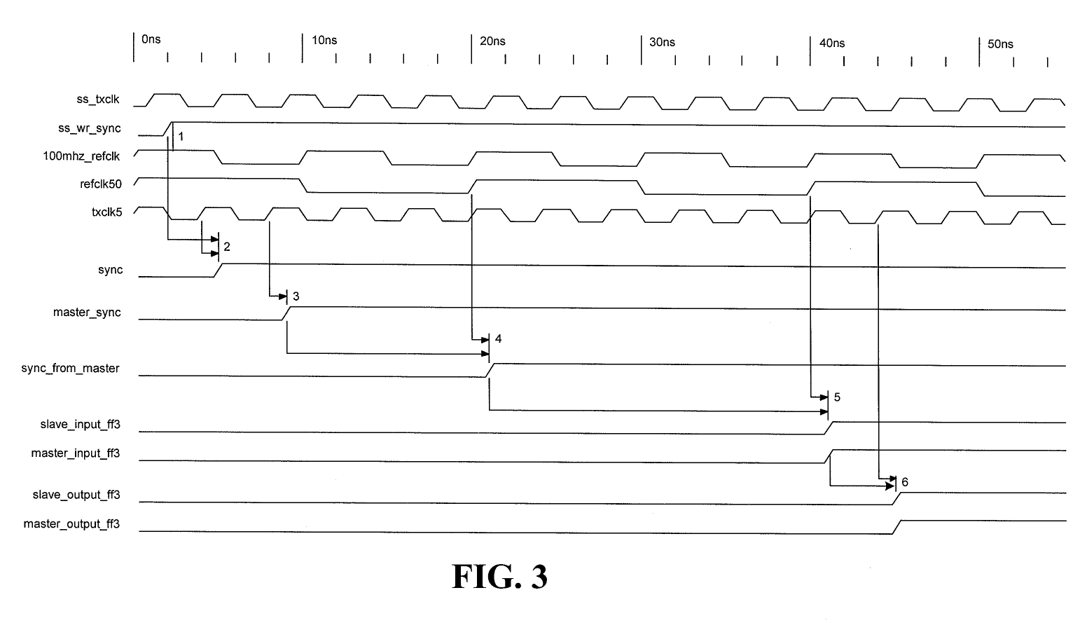

FIG. 3 shows a timing diagram for various signals, consistent with an example embodiment of the present invention; and

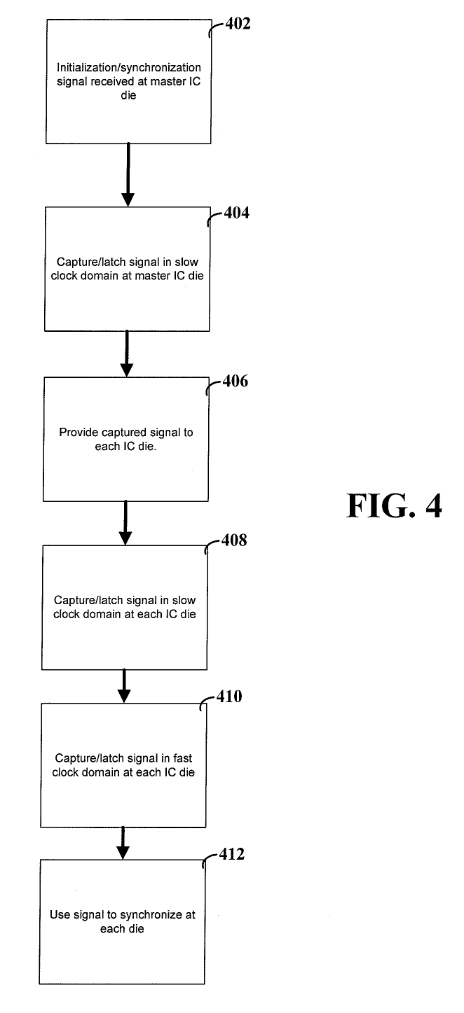

FIG. 4 shows a flow diagram for implementing a method, according to an example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention including aspects defined by the appended claims.

The present invention is believed to be applicable to a variety of different types of processes, devices and arrangements for use with various bus protocols, and in particular, to approaches for synchronizing a multi-lane bus that is implemented on different integrated-circuit (IC) dies. While the present invention is not necessarily so limited, various aspects of the invention may be appreciated through a discussion of examples using this context.

According to one embodiment of the present invention, a synchronization system is implemented between transmit circuits each located on a different IC die. A master circuit receives an external synchronization signal. The external synchronization signal is latched/captured into a local clock domain of one of the IC dies. The latched signal is sent to each of the transmit circuits. Each of the transmit circuits latches this signal into a respective local clock domain. The resulting signals are then used to synchronize the transmit circuits on each IC die.

In certain instances, each transmit circuit includes a link/lane, over which data is communicated. The data is interleaved between the lanes to provide a high data bandwidth system. One method of interleaving of data requires that the transmit circuits maintain synchronicity with each other. A specific example is provided by the PCI Express specification.

FIG. 1 is a block diagram that depicts a communication system, consistent with an example embodiment of the present invention. MAC 102 communicates with the PHY lanes 110, 120, 130 and 140. Each PHY represents a communication lane. MAC 102 sends and receives data to and from each of the PHY lanes. The PHY lanes of PHYs 110, 120, 130 and 140 send and receive data to and from PHY lanes of another device. In a particular embodiment, each lane is located on a different IC die.

Data transferred between the MAC and a PHY is stored in memory 104. This memory can be implemented using various memory technologies as well as various access methodologies. A specific example is a random-access memory circuit that functions as a first-in-first-out (FIFO) buffer. There can be a separate FIFO buffer for each of outgoing and incoming data. Many memory access methodologies employ read/write pointers to access data in the proper order. Certain PHY protocols, such as data interleaving, further require that the data is accessed in the proper order between multiple PHYs. This is accomplished by synchronizing the accesses via the pointers of each of the PHYs. Aspects of the present invention facilitate such synchronization.

According to an example embodiment of the present invention, a synchronization signal is provided to a master PHY 140. Master PHY 140 includes a synchronization circuit 106 that captures the synchronization signal in a local clock domain using, for example, one or more flip flops. The captured signal is then sent to each of the PHYs. Each of the PHYs, including master PHY 140, receives the synchronization signal. A synchronization circuit 108 captures the synchronization signal in a second, faster frequency, clock domain. In a specific embodiment, the second clock domain is phase-locked with the first clock domain using, for example, a phase-lock-loop (PLL) circuit. The resulting signal is then used internal to each PHY to ensure that data accesses in each PHY occur synchronously. In a specific embodiment, the final synchronization signal is used to synchronize pointers of respective FIFO buffers.

Aspects of the present invention are useful for assisting different PHY IC dies in a single cascaded-PHY solution. This can be particularly useful for facilitating flexible component selection.

Aspects of the present invention are also useful for implementing interchangeable PHYs. A specific embodiment allows the use of identical IC dies for each of the PHYs, thereby providing a simple and cost-effective implementation of various cascaded-PHY solutions. In such embodiments, the designer of the communications system need not design for different PHY dies (e.g., slave and master dies).

Another embodiment of the present invention allows for the IC dies to be implemented differently depending upon whether they are master or slave IC dies. Although FIG. 1 shows each PHY 110, 120, 130 and 140 as having the same set of components, the PHYs need not be identical. In one such embodiment, a master PHY can be implemented with the circuitry 106, while slave PHYs need not include circuitry 106.

The PCI Express Gen 1 specification requires that the transmit (Tx) lane to lane skew be less than 2UI (unit interval)+500 ps (i.e., 1300 ps). When multiple (e.g., 4×1) PHYs are used for a PCI Express link, aspects of the present invention involve implementing a synchronization mechanism between the PHYs to facilitate the meeting of timing requirements.

FIG. 2 shows a system for implementing a cascaded PHY, according to an example embodiment of the present invention. On the transmit side, each ×1 lane includes a de-skew buffer. This de-skew buffer can be implemented as a first-in-first-out (FIFO) buffer that can be accessed using write and read pointers. The data is written by the MAC into the write side of the de-skew buffer using a clock provided by the MAC (ss_txclk). The data is then accessed by the PHY using a local clock (txclk5). The phase relationship between ss_txclk and tclk5 can be unknown and undefined. The clocks are, however, frequency locked.

In a particular embodiment of the present invention, transmitted/received data crosses between the clock domains of ss_txclk and txclk5 while inside the FIFO buffer. The can be useful for avoiding a clock delay requirement between ss_txclk and txclk5, and consequentially useful for implementing the PHY on a different IC chip from the MAC.

One embodiment of the present invention facilitates cascading multiple lanes (e.g., a ×4 PHY) across different IC dies. To conform to the PCI Specification, data is loaded into the FIFO buffer synchronously between the multiple lanes. Similarly, data is read out of the FIFO buffer synchronously between the multiple lanes.

The MAC writes the data using a synchronous clock. The write-synchronization signal (wr_sync) is also generated by the MAC to allow for synchronization of the write pointers. Thus, the write operations are synchronously performed with the MAC clock domain.

To read out from the FIFO buffer, the present invention facilitates synchronization of each of the read pointers. Aspects of the present invention are used to generate a sync signal that is synchronous to each of the (4) internal clocks (txclk5) of the ×1 chips. Specifically, all the chips generate the internal txclk5 using a (100 Mhz) reference clock and a PLL. This reference clock is then internally divided (by 2) to generate a slower (50 mhz) clock. The phase relationship between the internal txclk5 is maintained with this slower (50 mhz) clock. Internally phase-synchronization between each txclk5 is maintained (e.g., due to the following clock derivations: a 100 Mhz clock is issued to generate a 50 Mhz clock, which is used to generate a 250 Mhz clock).

To synchronize the write pointers, a synchronization signal is provided. ‘txclk5’ is a fast clock (250 mhz), making it difficult to use between multiple IC chips. For instance, generating a signal using txclk5 in the first IC chip to be then transmitted to other IC chips is complicated by timing delays between IC chips. For example, the IC chip pads and the signal routing both contribute to timing delays in each of the lanes. Thus, it can be difficult to use a fast clock and still meet the setup and hold times of all the lanes. Specifically, a 250 mhz clock translates to a 4 ns time period. Embodiments of the present invention make use of a slower (50 mhz) clock when generating the sync signal. This slower (50 mhz) clock provides a larger timer period (20 ns), facilitating use in current technologies.

As shown in FIG. 2, a first IC chip is selected as the master. The selection can be done in various manners, including dynamically (e.g., by the MAC), or at the design stage (e.g., using board design or a non-volatile memory). During initialization of the PHYs, the master PHY receives a sync signal (ss_wr_sync) that is asynchronous to the transmit clocks of the PHYs. FIG. 2 shows this signal as being the same as the sync signal used to synchronize the write pointers; however, separate signals could be used for each of the write and read synchronizations. FIG. 2 also shows a sync_block, which can be used to condition or otherwise control aspects of the received sync signal. In a specific example, sync_block includes a circuit to transform the received sync signal into the transmit clock domain using, for example, a double synchronizer. This local sync signal is input to a flip-flop (ff1) that is clocked by a slower clock (refclk50) using, for example, a 50 mhz clock internal to the master chip. The transmit clock (txclk5) and the slower clock (refclk50) are phase-locked so there is no asynchronous clock domain crossing.

The signal synced to the refclk50 is called sync_from_master. This signal is sent to each of the cascaded slave IC chips. Each of the IC chips, including the master chip, capture this sync_from_master signal using a flip-flop (ff2) clocked by refclk50. The signal is then captured using a flip-flop (ff3) clocked by txclk5. The resulting signal is then used to synchronize the read pointers.

This synchronization can occur infrequently (e.g., only during initialization) because the internal clocks of each IC chip are generated from and phase-locked to the same clock (refclk50). Thus, once the PHY chips are synchronized by the sync signal/pulse, the synchronicity can be maintained internal to each chip. The synchronization pulse can also be responsive any number of different events. For instance, the sync signal can be generated after an event that causes the clocks to halt or otherwise lose synchronicity to one another. In another instance, the sync signal can be generated after detection of a communication-based error.

FIG. 3 shows a timing diagram for various signals, according to an example embodiment of the present invention. The diagram includes a number of clocks, sstxclk, 100 Mhz_refclk, refclk50 and txclk5. These clocks are supplied to a number of different flip-flops as the clock inputs thereto. The diagram also includes a number of signals, that represent the input and outputs from the different flip flops. These signals include ss_wr_sync, sync, master_sync, sync_from_master, slave_input_ff3, master_input_ff3, slave_output_ff3 and master_output_ff3. The general signal flow is as follows: ss_wr_sync becomes sync; sync becomes master_sync; master_sync becomes sync_from_master; sync_from_master becomes both slave_input_ff3 and master_input_ff3; slave_input_ff3 becomes slave_output_ff3, and master_input_ff3 becomes master_output_ff3.

Steps corresponding to times 1-4 are implemented at the master PHY, while steps corresponding to time 5 and 6 occur at each PHY. At time 1, the ss_wr_sync signal is toggled. At time 2, the sync signal toggles in response to the ss_wr_sync and the txclk5. This represents an optional implementation where the ss_wr_sync signal is first captured in the faster txclk5 domain. At time 3, the previously captured signal is further captured in the txclk5 domain. The combination of consecutive captures functions as a protection against meta-stability from timing violations due to the different clock domains. At time 4, the master_sync is captured in the refclk50 domain. The resulting sync_from_master signal is used by each PHY including the master PHY. Specifically, the sync_from_master signal is again captured by the refclk50 local to each PHY, as represented at time 5 by slave_input_ff3 and master_input_ff3. This signal is then captured, at time 6, in tclk5 domain to produce slave_output_ff3 and master_output_ff3. This signal represents the synchronization signal used within each PHY to provide synchronization therebetween.

A specific example of synchronization includes synchronization between rd_ptrs of the master and slave chips. Optionally, additional synchronization logic (rd_ptr_sync_logic) can be used. This logic can perform a variety of functions including, but not limited to, implementing a delay, providing a sequence of synchronization signals or providing a synchronization signal to the rd_ptrs contingent upon other inputs. The logic can be implemented using, for example, discrete logic, a processor or a finite-state-machine.

FIG. 4 shows a flow diagram for implementing a method, according to an example embodiment of the present invention. At step 402 an initialization signal is received at the master IC die. As discussed above, this signal can be asynchronous to the local clock domain(s) of the master IC die. At step 404, to avoid problems due to the signal crossing clock domains (e.g., meta-stability), the signal is first captured in a relatively slow clock domain that is synchronous to the master (and slave) IC dies. Due to the relatively slow frequency of this clock domain, the likelihood of violating setup or hold times can be reduced (i.e., relative to capturing using a faster clock). At step 406, this captured signal is then sent to each (slave) IC die. At step 408, the sent signal is captured again in the slow clock domain at each IC die including the master IC die. This second capture of the signal further reduces the likelihood of violating setup or hold times. At step 410, the signal is captured in a faster clock domain that is synchronous to the slower clock domain. In a particular embodiment, the synchronicity is due to the clocks being derived from the same reference clock using, for example, a phase-locked loop (PLL). For example, the slower clock domain can be a reference clock that is common to each of the IC devices, while the faster clock domain is a clock derived from a PLL. Due to the local nature and separate generation of the fast clocks each local, fast clock can be slightly different (e.g., due to PLL variations); however each clock is synchronous to the common reference clock. Accordingly, this capture can be useful in providing further protection against violations of setup or hold times and also to maintain the signal within the faster clock domain parameters at each IC die. At step 412, the signal is then used to synchronize the transmit PHYs of each IC die to one another. In a specific implementation, the signal synchronizes read pointers to local FIFO memory buffers.

Embodiments of the present invention allow for variations on the specific implementations and timings shown in the figures herein. For example, additional latches/flip-flops can be added into the system to help increase the mean-time between failures (MTBF) due to meta-stability issues at the cost of additional delay in the synchronization signal.

While the present invention has been described above and in the claims that follow, those skilled in the art will recognize that many changes may be made thereto without departing from the spirit and scope of the present invention.

What is claimed is:

1. A method for synchronizing data transfers between integrated-circuits (IC) of a plurality of IC dies, each IC die including a physical layer (PHY) and a communication lane, the method comprising:
in a first IC die of the plurality of IC dies,
receiving a synchronizing signal;
latching the synchronizing signal in a first clock domain and in the first IC die to produce a first latched output signal; and
providing the first latched output signal for use by each of the plurality of IC dies; and
in each of the plurality of IC dies,
further latching the first latched output signal in the first clock domain to produce a second latched output signal;
further latching the second latched output signal in a second clock domain to produce a third latched output signal; and
using the third latched output signal to synchronize a respective communication lane,
wherein the second clock domain is phase-locked with the first clock domain and a frequency of second clock domain is faster than a frequency of the first clock domain.

2. The method of claim 1, wherein synchronizing a respective communication lane includes synchronizing respective write pointer registers.

3. The method of claim 1, wherein the second clock domain is 250 Mhz and the first clock domain is 50 Mhz.

4. The method of claim 1, wherein the first clock domain and the second clock domain are each derived from a reference clock domain that is provided to each IC die.

5. The method of claim 1, wherein each communication lane is a serial communication lane and wherein data is striped between each communication lane.

6. The method of claim 5, wherein interpreting data carried on the communications lanes relies upon synchronization between the communication lanes.

7. The method of claim 1, wherein the synchronizing signal is an initialization signal generated by a medial access controller (MAC).

8. A device for synchronizing data transfers between integrated-circuits (IC) dies of a plurality of IC dies, each IC die including a physical layer (PHY) and a communication lane, the device comprising:
in a first IC die of the plurality of IC dies that receives a synchronizing signal;
a master circuit to latch the synchronizing signal in a first clock domain and to produce a first latched output signal and to provide the first latched output signal for use by each of the plurality of IC dies; and
in each of the plurality of IC dies,
a first circuit for latching the first latched output signal in the first clock domain to produce a second latched output signal;
a second circuit for latching the second latched output signal in a second clock domain to produce a third latched output signal; and
a third circuit for using the third latched output signal to synchronize a respective communication lane,
wherein the second clock domain is phase-locked with the first clock domain and a frequency of second clock domain is faster than a frequency of the first clock domain.

9. The device of claim 8, wherein synchronizing a respective communication lane includes synchronizing respective write pointer registers.

10. The device of claim 8, wherein the second clock domain is 250 Mhz and the first clock domain is 50 Mhz.

11. The device of claim 1, wherein the first clock domain and the second clock domain are each derived from a reference clock domain that is provided to each IC die.

12. The device of claim 1, wherein each communication lane is a serial communication lane and wherein data is striped between each communication lane.

13. The device of claim 5, wherein interpreting data carried on the communications lanes relies upon synchronization between the communication lanes.

14. The device of claim 8, wherein the synchronizing signal is an initialization signal generated by a medial access controller (MAC).

15. A system for synchronizing data transfers between integrated-circuits (IC) dies of a plurality of IC dies, each IC die including a physical layer (PHY) and a communication lane, the system comprising:
a control circuit for generating a synchronizing signal;
in a master IC die of the plurality of IC dies that receives the synchronizing signal;
a master circuit to latch the synchronizing signal in a first clock domain and in the first IC die to produce a first latched output signal and to provide first latched output signal to each of the plurality of IC dies; and
in each of the plurality of IC dies,
a first circuit for latching the first latched output signal in the first clock domain to produce a second latched output signal;
a second circuit for latching the second latched output signal in a second clock domain to produce a third latched output signal; and
a third circuit for using the third latched output signal to synchronize a respective communication lane,
wherein the second clock domain is phase-locked with the first clock domain and a frequency of second clock domain is faster than a frequency of the first clock domain.

16. The system of claim 15, wherein synchronizing a respective communication lane includes synchronizing respective write pointer registers.

17. The system of claim 15, wherein the second clock domain is 250 Mhz and the first clock domain is 50 Mhz.

18. The system of claim 15, wherein the first clock domain and the second clock domain are each derived from a reference clock domain that is provided to each IC die.

19. The system of claim 15, wherein each communication lane is a serial communication lane and wherein data is striped between each communication lane.

20. The system of claim 19, wherein interpreting data carried on the communications lanes relies upon synchronization between the communication lanes.

21. The system of claim 15, wherein the synchronizing signal is an initialization signal generated by a medial access controller (MAC).
